(19) United States
(12) Patent Application Publication
(10) Pub. No.: US 2019/0348943 A1
(43) Pub. Date: Nov. 14, 2019

(54) Solar Panel Apparatus and Method

(71) Applicant: Salah S. Sedarous, Rochester, MN (US)

(72) Inventor: Salah S. Sedarous, Rochester, MN (US)

(21) Appl. No.: 16/241,478

(22) Filed: Jan. 7, 2019

Related U.S. Application Data
(60) Provisional application No. 62/614,065, filed on Jan. 5, 2018.

(51) Int. Cl. H02S 30/10; H02S 40/22; H01L 31/042

(52) U.S. Cl. CPC H02S 30/10; H01L 31/042; H02S 40/22

(57) ABSTRACT

A solar collection system includes a solar panel. The solar panel further includes a first major surface, a second major surface, a first end, and a second end. The first end is positioned near the second end to form a device where solar energy is collected on a portion of the first major surface and a portion of a second major surface of the solar panel. In one embodiment, the first end is connected to the second end to form an annular-shaped, or oval-shaped solar panel.

### FIELD OF THE INVENTION

The invention relates to solar panel apparatus and methods which are used to generate electricity. The invention describes several embodiments and configurations that provide examples of the invention.

### BACKGROUND OF THE INVENTION

The need for electricity is growing at alarming rate as the world is progressing in all parts of the planet. In addition, there are more than one billion people, who have little or no access to electricity. Access to energy in general and to electricity in particular is strongly linked to the expanding of prosperity. Major source of electricity is from fusel fuel; however, with the increase awareness of their impact on the environment, a new cleaner source of electricity has to be developed. The production of new sources of electricity has to come from renewable sources in order to sustain a clean environment.

The interesting fact is that the incoming daily amount of solar energy reaching the earth's surface are enormous and enough to provide the energy needs of the entire world. Nevertheless, in order to harvest this energy, there is a continuous and urgent need for creating efficient and creative methods for that purpose. The main barrier to the conversion of the incoming solar energy to electricity and the wide use of photoelectric technology is its high cost (mainly installation) which is coming down rapidly, the low efficiency of thin film technology, and the limited number of peak insolation hours available in most locations.

Currently, the main research thrust in solar energy focused on the increase of the solar cell efficiency and on the lowering of the cost of their manufacturing. The Increase of solar cell efficiency is not easy and it is growing at very slow base as illustrated in FIG. 1.

### SUMMARY OF THE INVENTION

A different approach for increasing solar energy without a fundamental change in the solar cells efficiency is to increase the numbers of photons that reach the surface areas of sun collectors—by focusing the sunrays, or by increasing the surface areas of solar panels. So far, surface areas increase has been done by placing thousands of solar panels in scarcely populated and isolated areas or on floating solar farms in order to harvest sun's energy using photo voltage cells technology. Nonetheless, there is an obvious mismatch between energy generation and energy consumption.

### DESCRIPTION OF THE DRAWINGS

FIG. 1 is a graph of efficiency vs calendar year which illustrates the efficiencies of different Photo voltages cells since about 1975.

FIG. 2 shows a 3-d cylinder configuration of solar panel, which contain 3 thin-films surfaces that are foldable in the vertical direction, according to an example embodiment.

FIG. 3 shows a plurality of solar cells used to charge a battery, which in turn provides power to a house or other system over time, including times when the sun is not shining, according to an example embodiment.

FIG. 4 is a perspective view of a solar cell having a first end and a second end which are positioned near one another, according to an example embodiment.

FIG. 5 is a perspective view of a solar cell having a first end and a second end which are connected to one another, according to an example embodiment.

FIG. 6 is a top view of the solar cell shown in FIG. 5 having a first end and a second end which are connected to one another, according to an example embodiment.

FIG. 7 is a top view of the solar cell shown in FIG. 5 having a first end and a second end which are connected to one another, according to an example embodiment.

FIG. 8 is a top view of the solar cell shown in FIG. 5 having a first end and a second end which are connected to one another, according to an example embodiment.

FIG. 9 is a perspective view of a system having a first solar cell and a second solar cell, the first solar cell has a first end and a second end which are positioned proximate one another, and the second solar cell has a third end and a fourth end which are connected to one another, according to an example embodiment.

FIG. 10 is a top view of a system having a first solar cell and a second solar cell, the first solar cell has a first end and a second end which are positioned proximate one another, and the second solar cell has a third end and a fourth end which are connected to one another, according to an example embodiment.

FIG. 11 is a top view of a system having a first solar cell and a second solar cell, the first solar cell has a first end and a second end which are positioned proximate one another, and the second solar cell has a third end and a fourth end which are connected to one another, according to an example embodiment.

FIG. 12 is a top view of a system having a first solar cell and a second solar cell, the first solar cell has a first end and a second end which are positioned proximate one another, and the second solar cell has a third end and a fourth end which are also positioned proximate to one another, according to an example embodiment.

FIG. 13 is a top view of a portion of a solar cell system, according to another example embodiment.

FIG. 14 is a perspective view of another solar cell system, according to another example embodiment.

FIG. 15 is a schematic view of another solar cell system, according to another example embodiment.

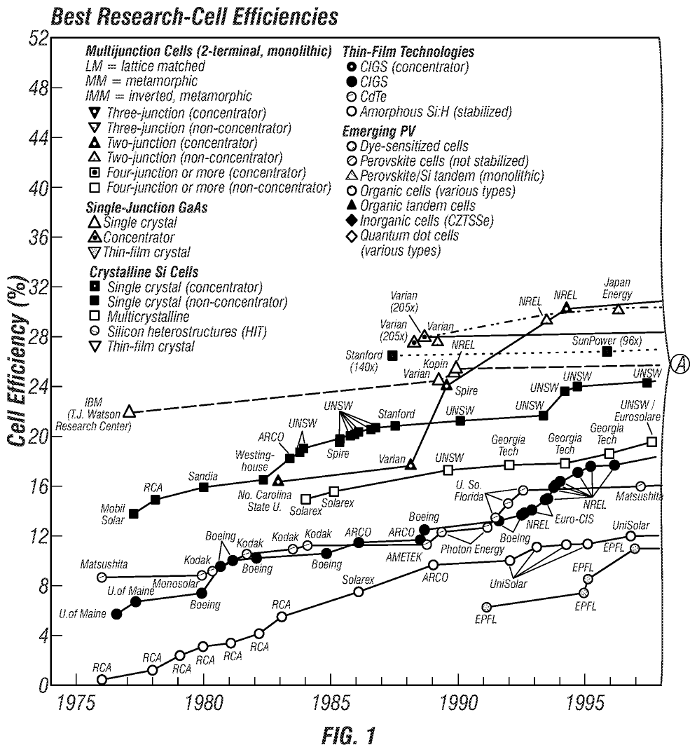

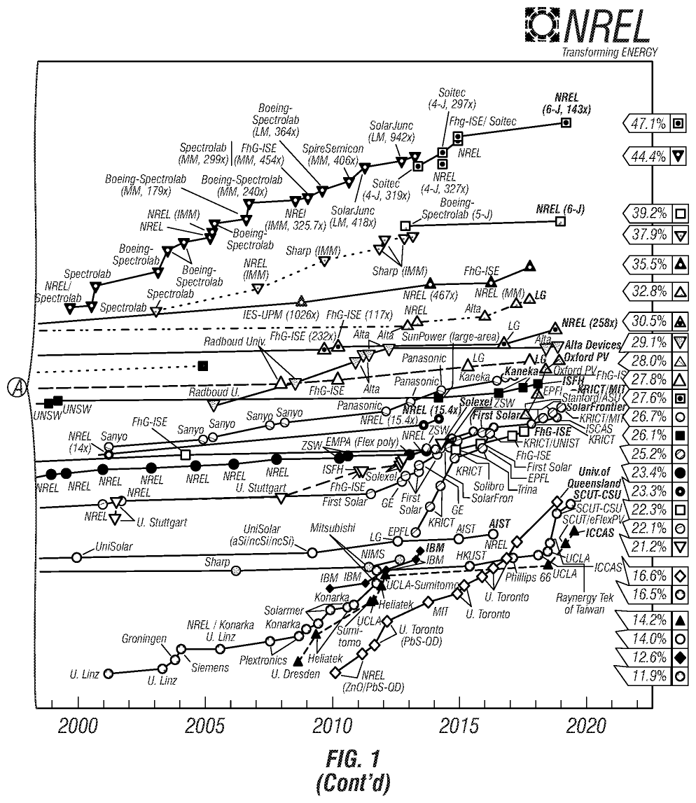

### DETAILED DESCRIPTION

In crowded cities and well-established communities, there is not enough space for solar farms; and therefore, there is an additional cost for transporting electricity from the productions at remote locations. For example, wind energy may be produced in a low population area. Infrastructure had to be added to various power companies power grids to transport the energy generated in rural areas to more highly populated areas needing the electricity. Adding infrastructure is time consuming and expensive.

In order to provide electricity to crowded places, there must be a way of maximizing electricity production per unite surface space in areas close to consumers. For example, instead of using the standard method of collecting electricity using 2-dimensional flat solar panels, electrical collection can be increased by adding the third spatial dimension to a solar collector.

In nature, trees and plants construct multiple methods for the collection of photosynthetic energy through complex 3-d structures and with an ingenious leaves distribution that maximizes photon collection while minimize water evaporation. These goals are achieved by the overall shapes of the trees, the leaves sizes, and the distribution of the leaves between top and the bottom. Generally, the leaves on the top are smaller than the leaves on the bottom—to allow light to reach the shaded area while minimizing the water loss at the top due to the direct exposure to the sun. On the microscopic scale, thylakoid membranes inside leaves (contain solar harvesting chromophore Chlorophylls) are organized in three-dimensional stacking configuration to maximize solar energy collection.

Topological shapes in nature have intrinsic thermodynamically characteristics related to their shapes and to the surface to volume ratios. For example, a simple Shape such as sphere has a minimum surface to volume ratio, while other uneven and unsymmetrical shapes have larger ratios. There are also a fundamental link between shapes and function, which is manifested in the different nature-made objects such protein, neurons and trees structures. For example, the hydrophobic residues in proteins induce the formation of tight closely packed structural conformation to shield these residues from water exposure, which affect the eventual function of a particular protein. Other proteins with hydrophilic structure can have different structures that provide other functions that involved these residues. Opened structures such as of neurons are designed in a way to enhance communication with other such structures by having tree-branches shapes configuration. Lungs and trees are designed with many sizes and scales of branches and vines to facilitate the exchanges of gases at the smallest scale of interfaces. Structures in nature are highly optimized according to their functions. Understanding the structure-function relationship in nature can give us many lessons on how to optimize manmade structures such solar panels using biomimicry. Shapes in nature are mostly exist in three-dimensional topological structures to optimize their given functions. The new 3-d solar panel design will follow those principles that govern natural objects.

Using nature as the ultimate designer, we examined the effect of projecting the manmade two-dimensional solar panel onto third dimension. For example, folding a 2-d flat panel of D length and height h, into a 3-d cylinder of the same height and of an equal diameter, increases the external surface area by a factor of three (3.14 or pi). The ratio of the two surfaces is π given the increase of the circumference in the folded state as follow:

$$\frac{{A}_{3 d}}{{A}_{2 d}} = \frac{π Dh}{Dh} = π$$

Cylindrical shapes are one of the simplest and structurally stable 3-d structures that can be considered for the 3-d solar panel configuration. The three fold (3.14) increase in the surface area by going into 3-d, can be further augmented by stacking multiple of such cylinders of various diameters in coaxial forms in the vertical direction.

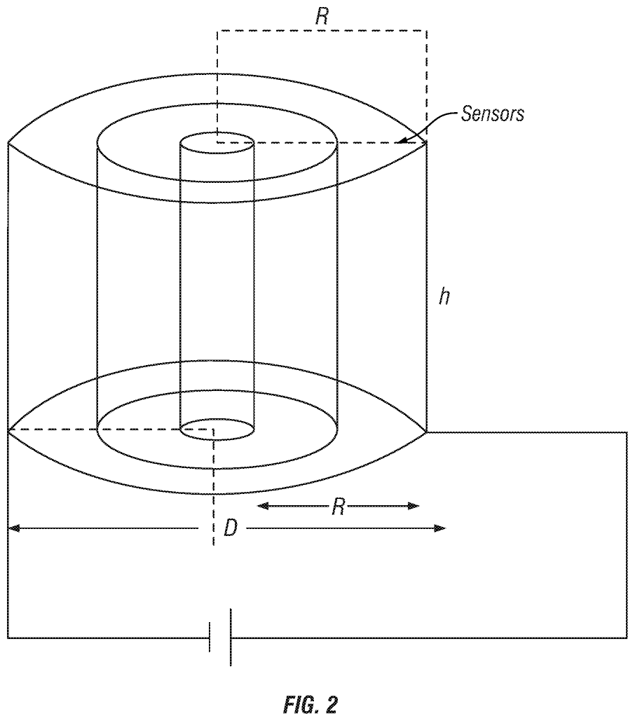

FIG. 2 shows a 3-d cylinder configuration 200 of a plurality of solar panels, according to one example embodiment. The 3-d cylinder configuration shown in FIG. 2 contains 3 thin-films surfaces that are foldable in the vertical direction, according to an example embodiment. The number of cylinders that are used here is for illustration only. Three are shown. It should be understood that a system can use different numbers of cylinders depending on the specific application and location. The solar cells can be located on the outside surfaces of a panel. In another configuration, the solar cells can be located on the inside surface with a light pipe on the top to illuminate the interior space when the structure is stretched vertically. The different types of sensors such as water, winds, and others can be positioned on the top surface to allow closing and opening of the folded cylinders according to the weather at the particular location. Electric energy collection could be stored in an under structure of batteries or super capacitors which can be used locally or uploaded to the electric grid for remote distribution.

Cylindrical geometry allows stacking of similar shapes in vertical space. Theoretically, if we place n cylinders of the same height and of equal radius r inside a larger cylinder of R radius, where R=nr, we obtain total surface areas of all extended cylinders as the following:

Total A=½(n+1)π

Therefore, if n=3, i.e., (such as the example embodiment shown in FIG. 2) we stack 3 cylinders in a tower shapes in a place of a 2-d flat panel with the outer cylinder of a diameter equal to the length the flat panel, the total sum of the surface area will be 2*pi>6 times the surface area of the single 2-d flat panel (See FIG. 2).

The table below shows the relationship between the number of coaxial 3-d solar collectors and the total surface area of the collectors in such a configuration. It should be noted that the table includes configurations of up to 7 coaxial solar collectors. There could be more nested within one another to make a solar collector system.

| Number of coaxial cylinders | Total surface areas in unit of Pi |
|---|---|
| 1 | 1 |
| 2 | 3/2 |
| 3 | 2 |
| 4 | 2½ |
| 5 | 3 |
| 6 | 3½ |
| 7 | 4 |

The cylindrical 3-D structural configuration provides many additional benefits besides optimizing space utility by providing the potential of stacking in vertical space. This structure could be designed to be foldable, flexible, mobile, efficient, cheap to construct, stable and easy to install in rural and urban areas. The simple new 3-d panel is suitable to install in restricted small horizontal space as on rooftops to provide electricity to multiple dwelling units or in rural area to provide electricity to small village and multiple homes in localities that are away from the grid. This design can help solve local needs of electricity with an impact on global scale. Another application of this design is to provide mobile electricity to outdoor recreational, business, sport, and military posts especially when these activities are located in outdoor and remote places.

Besides borrowing the overall cylinder configuration from nature via biomimicry, additional modification of this design can be found in nature. In plants, leaves are the main solar collector, therefore, the initial cylinder panel design is extremely flexible since it allows some extra solar collecting artificial leaves to be hanged from the bottom to allow collection of extra solar energy from the back or the front surfaces with the help of winds which can rotate the leaves around their rotating space. Additionally, hanging solar panel can be also incorporated into the cylindrical symmetry.

Another embodiment is to add light pipe from the central top of the panel to allow light activation of interior solar films beside the outside film, and therefore almost double the collecting surface areas.

Another embodiment is to add multiple sensors on the outside of the solar panels. The first one is a rain sensor, which when activated allows the panels to close in a tight wet barrier enclosure and to reduce the exposure to rains. The thin film solar panel should be able to handle some water exposures during normal operation. Another addition is a wind speed sensor, which activates folding of the solar panel in case of high wind conditions.

There is no energy generation during the night, therefor; a light sensor could be implemented to fold the solar panel when the outside light is less than 10% of daily peak values. The light switch sensor can also be used to fold the panel in cases of the presence of smoke or sand storm. This can protect the panels from physical damages during fire or flood.

Electric storages can be added to the new solar panels by novel stacking of graphene supper capacitances at the base or using standard storage batteries.

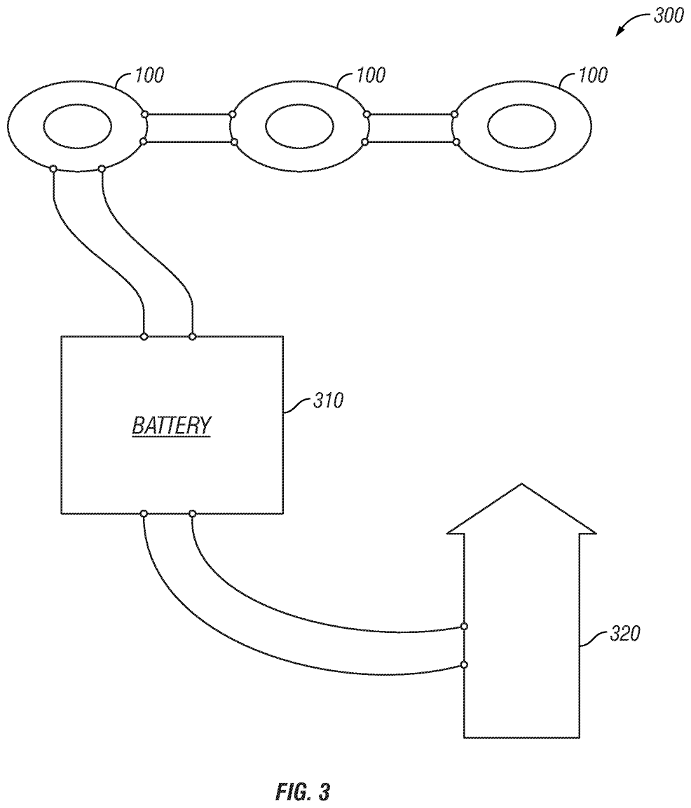

FIG. 3 shows a system 300 that includes a plurality of solar cell systems 100 attached in parallel to a battery 310, according to an example embodiment. The plurality of solar cell systems are used to charge the battery 310. The battery 310, in turn, provides power to a house 320 or other system over time, including times when the sun is not shining, according to the example embodiment. In another embodiment, a super capacitor is substituted for the battery 310. The load in this example is a house 320. It should be noted that this is one example of a load to which power or electrical energy is input.

The Current 3-D designs versus some other configurations:

Different 3-d designs were suggested by other research group to increase solar energy production. A group from MIT design 3-d panel by arranging the 2-d panels in an opened box format. They did some theoretical and experimental study of the enhancement of the output power due to the new configuration. They observed many folds increase in the output by arranging the flat panels in box shapes. Another design of the same group is to place the panels in pairs facing East/West directions in order to collect sun energy in forward and back configuration. The same pairs were arranged in a zigzag forms on top of one and another in a vertical arrangements. One weakness of the above design is the lack of scalability in the vertical direction. Arranging and placing top opened cubes on vertical direction is not mechanically stable. In addition, as the height increase the amount of sun reaching the bottom becomes very small given the direction of the sun relative to the vertical access. Even if solar panel were arranged on the inside beside the outside, the light collected from the inside arrangement is minimal. Cubic arrangement will accumulate sands and dirt due to its pocket shapes which degrades the performance of the system overtime. In general, sharp edge structures or objects are not common in nature since they are highly unstable according to biomimicry.

Additionally, heating and light illumination is this square structure will be varied greatly during day and light. Heat accumulation in the zigzag arrangement can create hot spots and shortening the lifetime of these panels.

Our design allows the collection of sunlight from the inside and the outside of the cylindrical symmetry due to the following: 1—By lacing light pipe at the top center of the 3-d panel structure, 2—the cylinder structure coupled with the light pipe allows the sun to propagate downward as it hit the top of the solar panel. As the sun moves across the sky the light intensity impending on the inside/outside change during the day, illuminating the whole structure.

Additional practical benefits of the current design is related to heating. The opened cylinder structures allows heat to circulate away from the structure since any accumulated heat rises upward in parallel to the vertical access which keeps the temperature of the solar panel cooler than traditional 2-d design in hot climates. Additionally, the vertical arrangements of the panels will slow down dust or snow accumulation, which in general, greatly degrades the performances of the flat panels in desert or in snowy locations. Dirt and snow on solar panels can drastically reduce their collecting efficiency by reducing the amount of sunrays that reaches the solar cells.

The cylindrical design we propose here became possible with the development of solar thin film technology. First generations solar cells were made from crystalline silicon, which are expensive, bulky and mechanically rigid. The second generations of solar cells are made of thin film of a thickness of nanometer to micrometer, which make them light, flexible and cheaper. The flexibility of thin film allows the possibility of rearrangement in three-dimensional shapes, tree-like pattern to increase their effective surface areas.

Another practical benefit of the cylindrical panel design is related to its weight and size. The new 3-d solar panel configuration can be positioned on the top of a typical gas station to transform them to a charging station without adding additional complex structure or extensive modification of their current structures. This can accelerate the adaptation of electric car technology by providing shorter distances between charging locations. This can take off easily, if the charging time is becoming much shorter with the use super capacitors technique. Moreover, collection of sun energy will require the increase of electric storage technology at each charging or gas station. Having a large electric storage capacity which geographically are widely distributed accelerates the transformation to the new smart grid. In summary, the wide adaptation of renewable PV power generation will improve electric energy supply, energy storage technology and will aid the modernization of the nation's electric grid.

In places outside the developed countries, the impact of this technology extends a revolution to worldwide population since it will provide an adequate local electricity to the poor and to those who live in isolated communities everywhere. The main trust of this technology is to maximize electricity generation of a given space. Therefore, this design could bring down the cost renewable energy to many people. The extra electricity enhances the standard of living in not only the developed nation but also in the underdeveloped urban areas worldwide.

The following is a small list of some of the advantageous of the new cylindrical design of solar panels:
1. Light weight since it uses thin film technology
2. Requires smaller base space
3. Foldable
4. Mobile, can easily folded and moved to a new location
5. Cheaper than standard crystalline Si cells
6. Output power is scalable due to foldability
7. Easily to implement in emergency and national disastrous situation by bring immediate electricity to these locations
8. Function in remote and outdoor locations
9. Excellent additional electricity source in crowded urban areas of underdeveloped countries in which electricity sources are not reliable
10. Provide electricity to communities living away from national grid or the countryside of underdeveloped countries
11. Electric source for those who prefer to live off the grid
12. Provide shorter distance between charging station
13. Accelerate the development of smart grid
14. Will lead to enhance electric storage technology
15. Provide affordable electricity
16. Contribute to clean environment worldwide

In addition to the above configurations, there are many more possible configurations. The following paragraphs discuss just a few of the possible configurations. It should be noted that any number of 3-D solar panels can be used to form various configurations for solar collection systems.

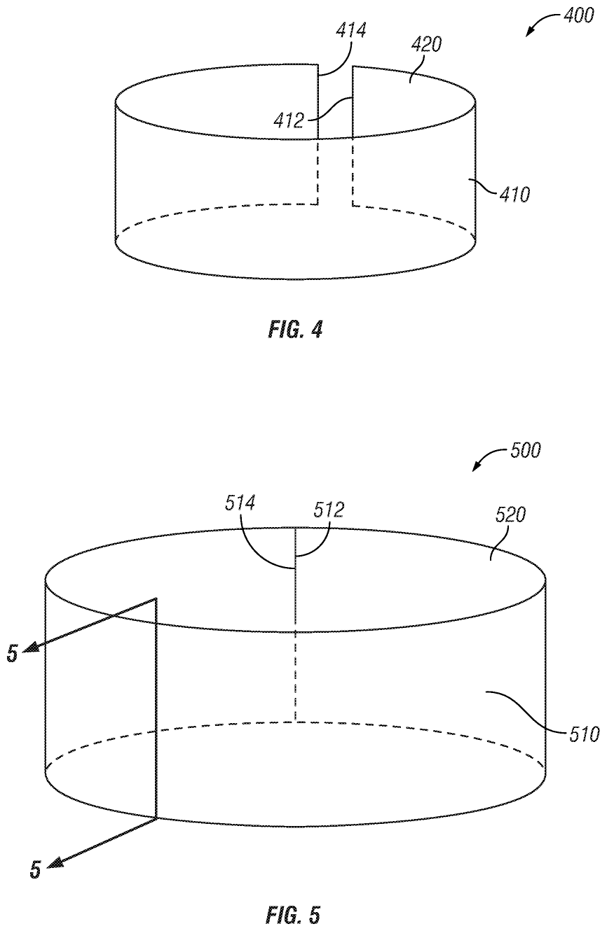

FIG. 4 is a perspective view of a solar cell 400 having a first end 412 and a second end 414 which are positioned near one another, according to an example embodiment. The solar cell has a first major surface 410 and a second major surface 420. The first end 412 and the second end 414 do not connect. The solar cell 400 can be foldable and include fold lines. In another embodiment, the solar cell 400 may not include fold lines.

FIG. 5 is a perspective view of a solar cell 500 having a first end 512 and a second end 514 which are connected to one another, according to an example embodiment. The solar cell 500 has a first major surface 510 and a second major surface 520. The first end 512 and the second end 514 connect or contact one another. The solar cell 500 can be foldable and include fold lines. In another embodiment, the solar cell 500 may not include fold lines.

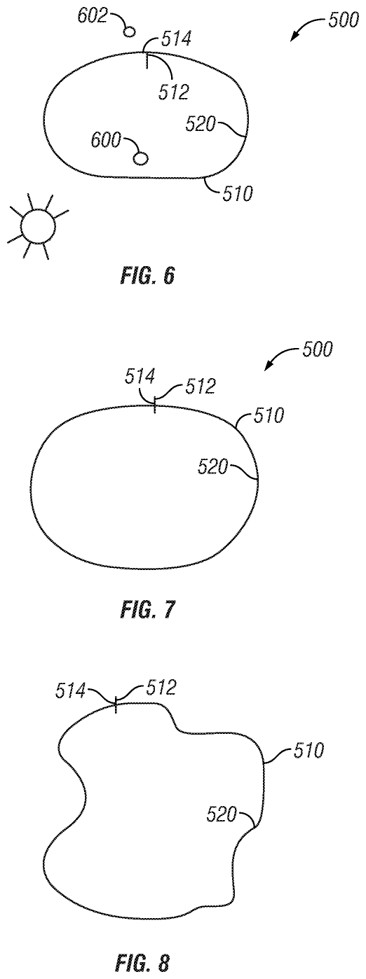

FIG. 6 is a top view of the solar cell 500 shown in FIG. 5 having a first end 512 and a second end 514 which are connected to one another or closely positioned near one another, according to an example embodiment. The top view shows that the solar cell in this example embodiment is substantially oval shaped. Different shapes could be used for different applications or to fit in various applications. Also shown is the sun 610. The sun 610 is placed in a position along one side of the solar cell 500. The sun will illuminate or shine on portions of the major surface 510 and on the major surface 520. A light channel 600 can be positioned near a shadowed portion of one major surface, such as the shadowed portion of major surface 520. Another light channel 602 can also be positioned near the shadowed portion of major surface 510. It should be noted that additional light channels can be positioned near the major surfaces to boost the output from the solar collector.

FIG. 7 is a top view of the solar cell 500 shown in FIG. 5 having a first end 512 and a second end 514 which are connected to one another or closely positioned near one another, according to an example embodiment. The top view shows that the solar cell in this example embodiment is substantially circularly shaped when viewed from the top. Of course, the solar cell will be substantially cylindrically shaped. Different shapes could be used for different applications or to fit in various applications. Although not shown, light channels could be positioned near the shaded major surfaces to increase output from the solar cell.

FIG. 8 is a top view of the solar cell 500 shown in FIG. 5 having a first end 512 and a second end 514 which are connected to one another or closely positioned near one another, according to an example embodiment. The top view shows that the solar cell in this example embodiment is irregularly shaped when viewed from the top. Different shapes could be used for different applications or to fit in various applications. Although not shown, light channels could be positioned near the shaded major surfaces to increase output from the solar cell. Again, one or more light channels could be used to enhance the output of the solar cell shown in FIG. 8.

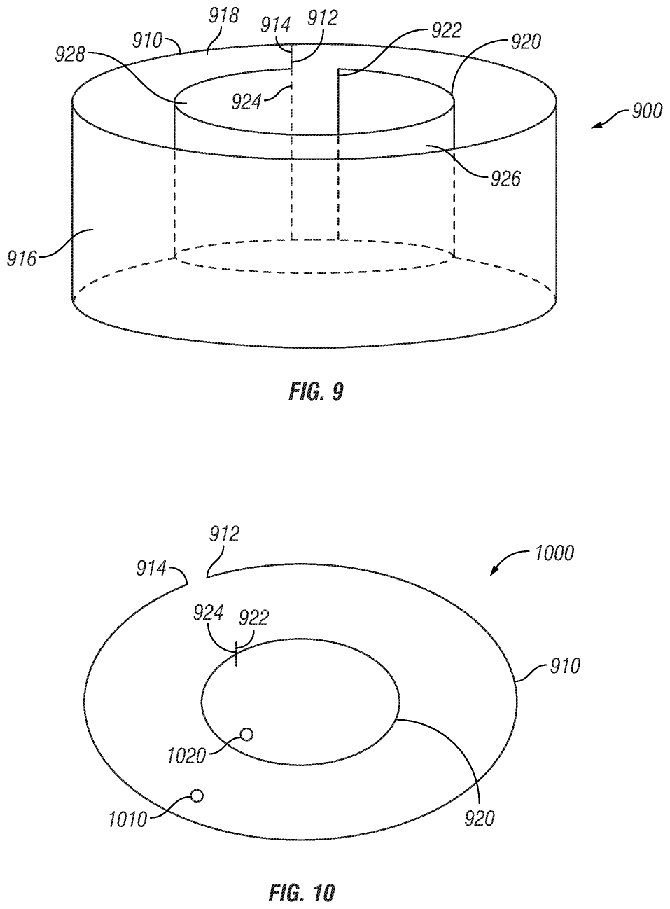

FIG. 9 is a perspective view of a system 900 having a first solar cell 910 and a second solar cell 920, the first solar cell 910 has a first end 912 and a second end 914 which are positioned proximate one another, and the second solar cell has a third end 922 and a fourth end 924 which are connected to one another, according to an example embodiment. The first solar cell 910 has a first major surface 916 and a second major surface 918. The second solar cell 920 has a first major surface 926 and a second major surface 928. In this example, one of the solar cells is connected and the other is disconnected. Any arrangement of solar cells can be used in such a system

FIG. 10 is a top view of a system 1000 having a first solar cell 910 and a second solar cell 920, the first solar cell 910 has a first end 912 and a second end 914 which are positioned proximate one another, and the second solar cell 920 has a third end 922 and a fourth end 924 which are connected to one another, according to an example embodiment. This is an example of another configuration of the solar cell shown in FIG. 9. The sun 930 is also shown in relation to the system 1000. Light pipes or channels 1010, 1020 are positioned near the shaded major surfaces of the first solar cell 910 and the second solar cell 920, respectively.

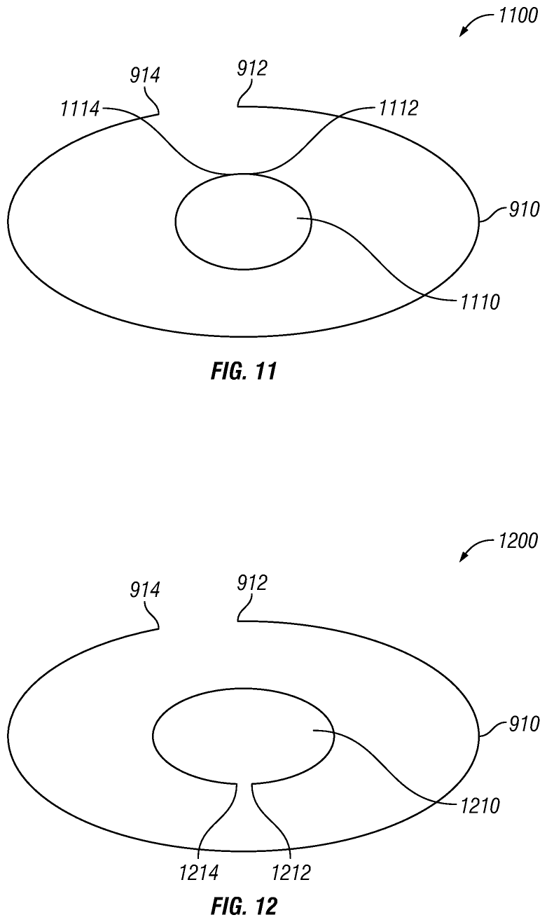

FIG. 11 is a top view of a system 1100 having a first solar cell 910 and a second solar cell 1110, according to another example embodiment. The first solar cell has a first end 912 and a second end 914 which are positioned proximate one another. The second solar cell has a third end 1112 and a fourth end 1114 which are connected to one another. This particular embodiment has solar cells of different shapes. One solar cell is cylindrical and appears as a circle in the top view. The other is oval shaped. Thus, different shaped cells can be coupled with one another to form a system, such as the system 1100.

FIG. 12 is a top view of a system 1200 having a first solar cell 910 and a second solar cell 1210, according to another example embodiment. The first solar cell has a first end 912 and a second end 914 which are positioned proximate one another. The second solar cell has a third end 1112 and a fourth end 1114 which are not connected to one another but are rather positioned proximate one another. This particular embodiment has solar cells of different shapes. One solar cell is cylindrical and appears as a circle in the top view. The other is oval shaped. Thus, different shaped cells can be coupled with one another to form a system 1200.

In still a further embodiment, the solar cell can be attached to a base that includes tracking of the sun. The base can be moved to track the sun. In still another embodiment, the movements can be made on the basis of maximizing output from the attached panel. The movements can be implemented robotically, and the system can include a feedback control unit that monitors power output vs. position of the solar cell. Of course, this installation can be on a building or other permanent structure. It could also be used for temporary set ups for collecting solar energy.

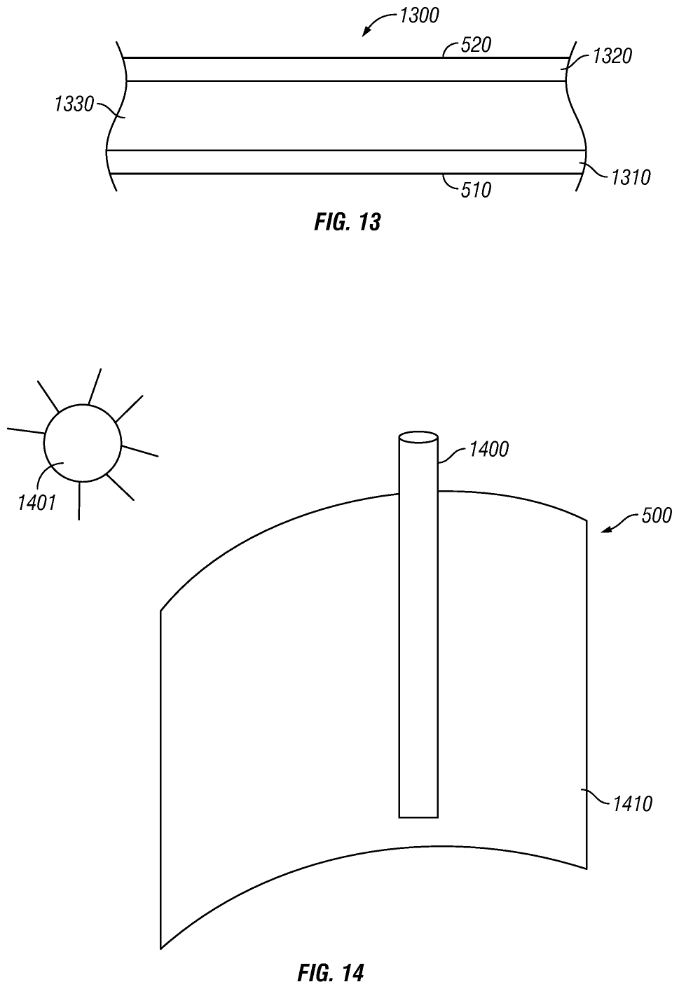

FIG. 13 is a top view of a portion of a solar cell system, according to another example embodiment.

FIG. 14 is a perspective view of another solar cell system, according to another example embodiment.

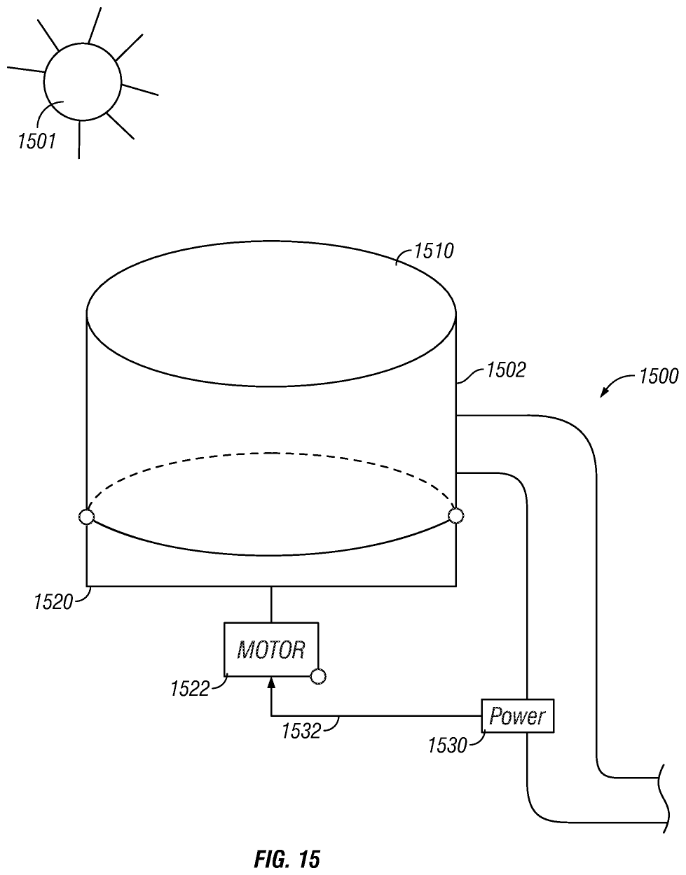

FIG. 15 is a schematic view of another solar cell system, according to another example embodiment.

A solar collection system includes a solar panel. The solar panel further includes a first major surface, a second major surface, a first end, and a second end. The first end is positioned near the second end to form a device where solar energy is collected on a portion of the first major surface and a portion of a second major surface of the solar panel. In one embodiment, the first end is connected to the second end to form an annular shaped solar panel. The annular shaped solar collection system is cylindrically shaped, in a further embodiment. In another embodiment, the solar panel is oval shaped and in yet another embodiment the solar panel is irregularly shaped. In other words, annular but not geometrically regular.

A solar collection system includes a first solar panel and a second solar panel. The first solar panel further includes a first major surface, a second major surface, a first end, and a second end. The first end is positioned near the second end to form a device where solar energy is collected on a portion of the first major surface and a portion of a second major surface of the solar panel. The second solar panel includes a third major surface, a fourth major surface, a third end; and a fourth end. The third end is positioned near the fourth end to form a device where solar energy is collected on a portion of the third major surface and a portion of a fourth major surface of the second solar panel. The second solar panel fits inside the second solar panel. In one embodiment, the first end is connected to the second end to form an annular shaped first solar panel, and the third end is connected to the fourth end to form an annular shaped second solar panel. In one embodiment. the first annular shaped solar panel is cylindrically shaped. In another embodiment, the first annular shaped solar panel is oval shaped. In still another embodiment, first annular shaped solar panel is irregularly shaped. In another embodiment, the first end of the first solar panel and the second end of the first solar panel are positioned near one another at a position where at least one end of the solar panel faces the sun. In still another embodiment of the solar collection system, the first solar panel is similarly shaped to the second solar panel while in another embodiment of the solar collection system, the first solar panel shaped differently than the second solar panel. In one embodiment, a plurality of annularly shaped solar collection panels nested within one another. The solar collection panels can be similarly shaped or differently shaped. In still another embodiment, at least one of the plurality of solar collection panels includes one where the ends of the panels are disconnected.

It is contemplated that various configurations of cells can be used to form systems for generating energy from variously shaped solar cells.

What is claimed is:

1. A solar collection system comprising:
a solar panel further comprising:
a first major surface;
a second major surface;
a first end; and
a second end, the first end positioned near the second end to form a device where solar energy is collected on a portion of the first major surface and a portion of a second major surface of the solar panel.

2. The solar collection system of claim 1 wherein the first end is connected to the second end to form an annular shaped solar panel.

3. The solar collection system of claim 2 wherein the annular shaped solar panel is cylindrically shaped.

4. The solar collection system of claim 2 wherein the annular shaped solar panel is oval shaped.

5. The solar collection system of claim 2 wherein the annular shaped solar panel is irregularly shaped.

6. The solar collection system of claim 2 wherein the first end of the solar panel and the second end of the solar panel are positioned near one another at a position where at least one end of the solar panel faces the sun.

7. A solar collection system comprising:
a first solar panel further comprising:
a first major surface;
a second major surface;
a first end; and
a second end, the first end positioned near the second end to form a device where solar energy is collected on a portion of the first major surface and a portion of a second major surface of the first solar panel; and
a second solar panel further comprising:
a third major surface;
a fourth major surface;
a third end; and
a fourth end, the third end positioned near the fourth end to form a device where solar energy is collected on a portion of the third major surface and a portion of a fourth major surface of the second solar panel.

8. The solar collection system of claim 7 wherein the second solar panel fits inside the second solar panel.

9. The solar collection system of claim 7 wherein
the first end is connected to the second end to form an annular shaped first solar panel; and
the third end is connected to the fourth end to form an annular shaped second solar panel.

10. The solar collection system of claim 9 wherein the first annular shaped solar panel is cylindrically shaped.

11. The solar collection system of claim 9 wherein the first annular shaped solar panel is oval shaped.

12. The solar collection system of claim 9 wherein first annular shaped solar panel is irregularly shaped.

13. The solar collection system of claim 9 wherein the first end of the first solar panel and the second end of the first solar panel are positioned near one another at a position where at least one end of the solar panel faces the sun.

14. The solar collection system of claim 8 wherein the first solar panel is similarly shaped to the second solar panel.

15. The solar collection system of claim 8 wherein the first solar panel shaped differently than the second solar panel.

16. A solar collection system comprising a plurality of annularly shaped solar collection panels nested within one another.

17. The solar collection system of claim 16 wherein the annularly shaped solar collection panels are similarly shaped.

18. The solar collection system of claim 16 wherein the annularly shaped solar collection panels include one solar panel shaped differently from the other of the plurality of annularly shaped solar collection panels.

19. The solar collection system of claim 16 wherein at least one of the plurality of solar collection panels includes one where the ends of the panels are disconnected.
